(19) United States
(12) Patent Application Publication
(10) Pub. No.: US 2024/0333219 A1
(43) Pub. Date: Oct. 3, 2024

(54) POWER AMPLIFICATION CIRCUIT

(71) Applicant: Murata Manufacturing Co., Ltd., Kyoto (JP)

(72) Inventor: Takashi SOGA, Kyoto (JP)

(21) Appl. No.: 18/616,643

(22) Filed: Mar. 26, 2024

(30) Foreign Application Priority Data
Mar. 29, 2023 (JP) 2023-053001

(51) Int. Cl. H03F 1/02; H03F 1/30; H03F 3/213

(52) U.S. Cl. CPC H03F 1/0216; H03F 1/302; H03F 3/213

(57) ABSTRACT

The power amplification circuit includes a first transistor that includes a base configured to receive a bias current or a bias voltage and that is configured to amplify an input signal and output a current and a second transistor that includes an emitter connected to the base of the first transistor and that is configured to supply the bias current to the base of the first transistor from the emitter. The power amplification circuit includes a comparison-voltage generation circuit configured to generate a comparison voltage based on an emitter current or voltage of the second transistor and a compensation circuit that is connected to the comparison-voltage generation circuit and that is configured to receive the comparison voltage and a reference voltage and generate a current with a decrease in the bias current or the bias voltage based on the comparison voltage and the reference voltage.

### CROSS REFERENCE TO RELATED APPLICATION

This application claims priority from Japanese Patent Application No. 2023-053001 filed on Mar. 29, 2023. The content of this application is incorporated herein by reference in its entirety.

### BACKGROUND OF THE DISCLOSURE

### 1. Field of the Disclosure

The present disclosure relates to a power amplification circuit.

### 2. Description of the Related Art

Power amplification circuits are used for power amplification of radio frequency signals. Demand for high-powered power amplification circuits is strong, and such demand has triggered approaches such as increasing a power-supply voltage provided to a power amplification circuit and increasing current flowing through an amplifying device in a power amplification circuit. In a power amplification circuit, a bias current or voltage and a signal to be amplified are inputted to an amplifying device, and power amplification is achieved. A change in a bias current or voltage may affect the operation of an amplifying device, and Japanese Unexamined Patent Application Publication No. 2015-222878 discloses a power amplification module designed to reduce a change in a bias current caused by manufacturing variation.

### BRIEF SUMMARY OF THE DISCLOSURE

Examples of a method to control output power of a power amplification circuit include managing the input power with the gain of the power amplification circuit kept constant and managing the gain of the power amplification circuit with the input power kept constant. If a method of managing the input power to control the output power is adopted, an amplifying device may operate in a saturated state. When an amplifying device is operated in a saturated state, the output power of the amplifying device needs to be increased, and high linearity (flatness of the gain) of the amplifying device is required. The output and linearity of the amplifying device is affected by a change in a bias current or voltage.

A bias current or voltage, which is a direct current (DC) component, and a signal to be amplified, which is an alternating current (AC) component, are inputted to an amplifying device. If a bias circuit configured to supply a bias current or voltage is not isolated from alternating-current input, an alternating-current signal is also drawn from the bias circuit. The bias current or voltage changes because of the alternating-current signal, and the DC operating point of the amplifying device changes as a result. The change in the DC operating point of the amplifying device affects the amplifying operation of the amplifying device, and the linearity of the power amplification circuit consequently deteriorates.

Accordingly, a possible benefit of the present disclosure is to provide a power amplification circuit capable of maintaining the linearity when power amplification with high output power is performed.

A power amplification circuit according to an aspect of the present disclosure includes: a first transistor that includes a base or a gate configured to receive a bias current or voltage and that is configured to amplify an input signal and output a first current; a second transistor that includes an emitter or a source connected to the base or the gate of the first transistor and that is configured to supply the bias current or voltage to the base or the gate of the first transistor from the emitter or the source; a comparison-voltage generation circuit configured to generate a comparison voltage based on an emitter current or voltage of the second transistor; and a compensation circuit that is connected to the comparison-voltage generation circuit and that is configured to receive the comparison voltage and a reference voltage and generate a compensation current with a decrease in the bias current or voltage based on the comparison voltage and the reference voltage.

According to embodiments of the present disclosure, it is possible to provide a power amplification circuit capable of maintaining the linearity when power amplification with high output power is performed.

### BRIEF DESCRIPTION OF THE SEVERAL VIEWS OF THE DRAWINGS

FIG. 1 is a circuit diagram of a power amplification circuit according to a first embodiment;

FIG. 2 is an example of a circuit diagram of a power amplification circuit according to a second embodiment;

FIG. 3 is an illustration describing the operation of the power amplification circuit according to the second embodiment;

FIG. 4 is an illustration describing the operation of the power amplification circuit according to the second embodiment;

FIG. 5 is an illustration describing the operation of the power amplification circuit according to the second embodiment;

FIG. 6 is a detailed circuit diagram of the power amplification circuit according to the second embodiment; and

FIG. 7 is a circuit diagram of a power amplification circuit according to a third embodiment.

### DETAILED DESCRIPTION OF THE DISCLOSURE

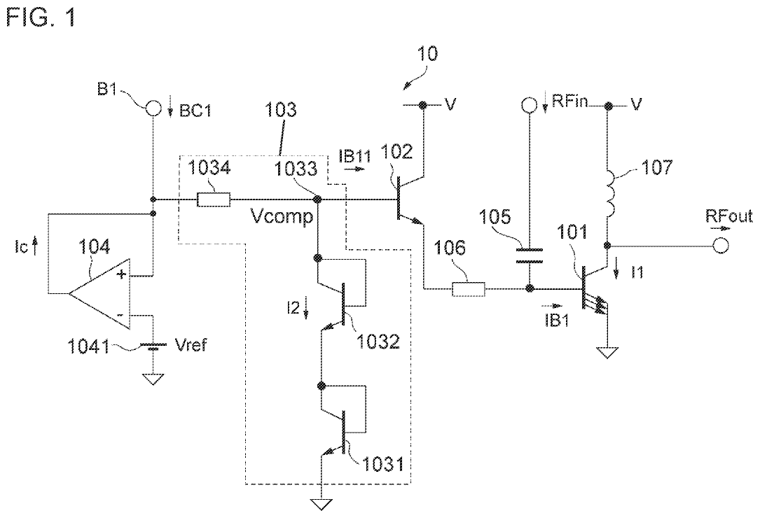

A first embodiment will be described herein. FIG. 1 is a schematic circuit diagram of a power amplification circuit according to the first embodiment. A power amplification circuit 10 includes transistors 101 and 102, a comparison-voltage generation circuit 103, a compensation circuit 104, a capacitor 105, a resistance element 106, and an inductor 107. The transistor 101 is configured to amplify an input signal RFin and output an output signal RFout from a collector.

The transistor 101 (first transistor) includes a base connected to the input terminal, the collector connected to the output terminal, and an emitter connected to the ground. The input signal RFin is inputted to the base. A bias current or voltage is supplied to the base of the transistor 101 from the transistor 102 described below. Description will be given herein with regard to an example in which a bias current IB1 is supplied to the base of the transistor 101. A power-supply voltage V is supplied to the collector of the transistor 101. A current I1 (first current) flows through the collector of the transistor 101.

In addition, the capacitor 105 is connected to the base of the transistor 101 to cut a direct-current signal in the input signal RFin. The inductor 107 is connected to the collector of the transistor 101 to reduce an alternating-current signal flowing into the power supply.

The transistor 102 (second transistor) includes an emitter connected to the base of the transistor 101, a collector connected to the power supply, and a base connected to a bias control terminal B1 with the comparison-voltage generation circuit 103, which is described below, interposed therebetween. The transistor 102 is configured to supply to the transistor 101 a bias current or voltage that depends on a bias control signal BC1 supplied from the bias control terminal B1. Description will be given herein with regard to an example in which a current IB11 (second current) is supplied to the base of the transistor 102 as a bias current. The resistance element 106 is disposed between the base of the transistor 101 and the emitter of the transistor 102.

The transistors 101 and 102 are each formed by a bipolar transistor such as a heterojunction bipolar transistor (HBT). Instead of an HBT, the transistors 101 and 102 may each be formed by a field-effect transistor such as a metal-oxide-semiconductor field-effect transistor (MOSFET). In the latter case, the terms “collector”, “base”, and “emitter” mentioned below may be replaced with the terms “drain”, “gate”, and “source”, respectively. The terms are also used in the same manner for the transistors described in other embodiments below.

The comparison-voltage generation circuit 103 is disposed between the base of the transistor 102 and the bias control terminal B1. The comparison-voltage generation circuit 103 includes transistors 1031 and 1032, a connection point 1033, and a resistance element 1034.

The transistors 1031 and 1032 are each a diode-connected transistor. The transistor 1031 includes an emitter connected to the ground. The transistor 1031 includes a collector connected to the emitter of the transistor 1032. The transistor 1032 includes a collector connected to the base of the transistor 102 with the connection point 1033 interposed therebetween. The collector of the transistor 1032 is also connected to the resistance element 1034 with the connection point 1033 interposed therebetween. The comparison-voltage generation circuit 103 is configured to generate a comparison voltage Vcomp at the connection point 1033 based on an emitter current or voltage of the transistor 102. It can also be said that the transistors 1031 and 1032 generate the comparison voltage Vcomp at the connection point 1033 based on a common current flowing through the transistors 1031 and 1032. The comparison voltage Vcomp is the voltage at the connection point 1033 and also the base voltage of the transistor 102.

The compensation circuit 104 is connected to the bias control terminal B1 and the comparison-voltage generation circuit 103. The compensation circuit 104 is connected to the base of the transistor 102 with the comparison-voltage generation circuit 103 interposed therebetween. The compensation circuit 104 is configured to receive a reference voltage Vref from a reference voltage source 1041 configured to generate the reference voltage Vref. The compensation circuit 104 is configured to supply a current Ic (compensation current) to the bias control terminal B1 side based on the comparison voltage Vcomp and the reference voltage Vref. The compensation circuit 104 is represented, for example, as a differential amplifier having a non-inverting input terminal and an inverting input terminal. As depicted in FIG. 1, the non-inverting input terminal of the compensation circuit 104 is connected to the bias control terminal B1 and the comparison-voltage generation circuit 103, and the inverting input terminal of the compensation circuit 104 is connected to the reference voltage source 1041. The output of the compensation circuit 104 is connected to the bias control terminal B1 and the comparison-voltage generation circuit 103.

The compensation circuit 104 is configured to generate the current Ic to increase the current IB11 with a decrease in the bias current or voltage of the transistor 101 based on the comparison voltage Vcomp and the reference voltage Vref.

The operation of the power amplification circuit 10 will be described.

In the power amplification circuit 10, the current I1, which depends on the input signal RFin and the bias current IB1, flows through the collector of the transistor 101.

The alternating-current input signal RFin is superimposed onto a direct-current bias voltage from the transistor 102 and is inputted to the base of the transistor 101. A changing alternating-current voltage is caused by the input signal RFin at the emitter of the transistor 102 at this time.

The changing alternating-current voltage caused at the emitter of the transistor 102 may decrease the base voltage of the transistor 102. For example, if the emitter voltage drops at the emitter of the transistor 102, the base-emitter voltage of the transistor 102 increases. As a result, a change occurs that increases the base current IB11 of the transistor 102. Consequently, the current I2 decreases that flows through the transistor 1031 and that generates the bias voltage at the transistor 102. The decrease in the current I2 decreases the comparison voltage Vcomp at the connection point 1033.

If the base voltage of the transistor 102 decreases, the bias voltage supplied by the transistor 102 to the transistor 101 also decreases. As a result, the degree of the amplification of the input signal RFin by the transistor 101 decreases, that is, the gain of the transistor 101 drops.

As the comparison voltage Vcomp decreases, a difference between the voltage at the non-inverting input terminal and the reference voltage Vref at the inverting input terminal increases. The compensation circuit 104 is configured to supply the current Ic to the bias control terminal B1 side based on the voltage difference.

Consequently, the current IB11 supplied to the base of the transistor 102 increases with the current Ic, that is, the current IB11 is compensated with the current Ic. As the current IB11 increases, the bias current IB1 supplied by the transistor 102 to the transistor 101 increases. An increase in the bias current IB1 maintains the bias voltage supplied by the transistor 102 to the transistor 101. In this way, the transistor 101 is able to amplify the input signal RFin more, that is, the gain of the transistor 101 increases. Since the power amplification circuit 10 is able to keep the gain of the transistor 101 high, the linearity of the gain of the power amplification circuit 10 is maintained.

A second embodiment will be described herein. In the second embodiment, features common to the first embodiment will be omitted, and only different features will be described. In particular, similar operations and similar advantages achievable by similar configurations will not individually be mentioned in each of the embodiments.

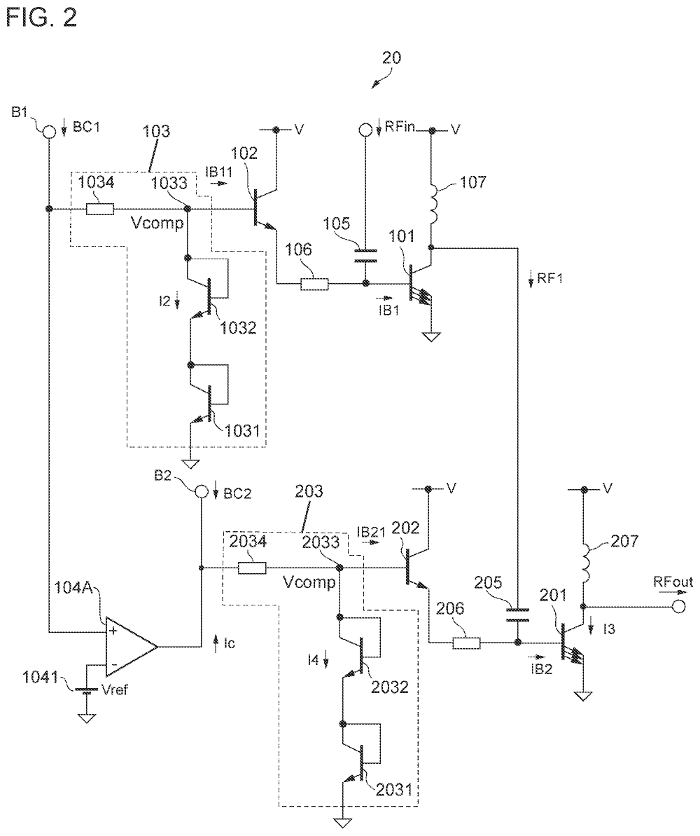

FIG. 2 is a schematic circuit diagram of a power amplification circuit 20 according to the second embodiment. The power amplification circuit 20 includes transistors 101 and 102, a comparison-voltage generation circuit 103, a compensation circuit 104A, a capacitor 105, a resistance element 106, an inductor 107, transistors 201 and 202, a comparison-voltage generation circuit 203, a capacitor 205, a resistance element 206, and an inductor 207.

In the power amplification circuit 20, the transistor 101 includes a collector connected to the base of the transistor 201 with the capacitor 205 interposed therebetween. In the power amplification circuit 20, the transistor 101 is configured to amplify an input signal RFin, which is inputted to the transistor 101, and output a signal RF1 (second input signal) from the collector. The transistor 201 is configured to receive the signal RF1, amplify the signal RF1, and output an output signal RFout. In other words, the power amplification circuit 20 is a multi-stage amplification circuit.

The power amplification circuit 20 differs from the power amplification circuit 10 according to the first embodiment in that the compensation circuit 104A is connected to the transistor 202 described below.

The transistor 201 (third transistor) includes a base connected to the collector of the transistor 101, a collector connected to the output terminal, and an emitter connected to the ground. A bias current or voltage is supplied to the base of the transistor 201 from the transistor 202 described below. Description will be given herein with regard to an example in which a bias current IB2 is supplied to the base of the transistor 201. A power-supply voltage V is supplied to the collector of the transistor 201. A current I3 (third current) flows through the collector of the transistor 201.

In addition, the capacitor 205 is connected to the base of the transistor 201 to cut a direct-current component in the signal RF1. The inductor 207 is connected to the collector of the transistor 201 to reduce an alternating-current signal flowing into the power supply.

The transistor 202 (fourth transistor) includes an emitter connected to the base of the transistor 201, a collector connected to the power supply, and a base connected to a bias control terminal B2 with the comparison-voltage generation circuit 203, which is described below, interposed therebetween. The transistor 202 is configured to supply to the transistor 201 a bias current or voltage that depends on a bias control signal BC2 supplied from the bias control terminal B2. Description will be given herein with regard to an example in which a current IB21 (fourth current) is supplied to the base of the transistor 202 as a bias current. The resistance element 206 is disposed between the base of the transistor 201 and the emitter of the transistor 202.

The comparison-voltage generation circuit 203 is disposed between the base of the transistor 202 and the bias control terminal B2. The comparison-voltage generation circuit 203 includes transistors 2031 and 2032, a connection point 2033, and a resistance element 2034. The comparison-voltage generation circuit 203 has a function similar to the function of the comparison-voltage generation circuit 103. The transistors 2031 and 2032, the connection point 2033, and the resistance element 2034 are connected as with the transistors 1031 and 1032, the connection point 1033, and the resistance element 1034 and each have characteristics similar to the characteristics of the corresponding component.

The compensation circuit 104A is connected to a bias control terminal B1, the comparison-voltage generation circuit 103, the bias control terminal B2, and the comparison-voltage generation circuit 203. The compensation circuit 104A is connected to the base of the transistor 202 with the comparison-voltage generation circuit 203 interposed therebetween. The compensation circuit 104A is configured to receive a reference voltage Vref from a reference voltage source 1041 configured to generate the reference voltage Vref. The compensation circuit 104A is configured to supply a current Ic (compensation current) to the bias control terminal B2 side based on the comparison voltage Vcomp in the comparison-voltage generation circuit 103 and the reference voltage Vref. The compensation circuit 104A is represented, for example, as a differential amplifier having a non-inverting input terminal and an inverting input terminal. As depicted in FIG. 2, the non-inverting input terminal of the compensation circuit 104A is connected to the bias control terminal B1 and the comparison-voltage generation circuit 103, and the inverting input terminal of the compensation circuit 104A is connected to the reference voltage source 1041. The output of the compensation circuit 104A is connected to the bias control terminal B2 and the comparison-voltage generation circuit 203.

The compensation circuit 104A is configured to generate the current Ic to increase the current IB21 with a decrease in the bias current or voltage of the transistor 101 based on the comparison voltage Vcomp generated by the comparison-voltage generation circuit 103 and the reference voltage Vref.

The operation of the power amplification circuit 20 will be described.

As in the power amplification circuit 10, a current I1, which depends on the input signal RFin and the bias current IB1, also flows through the collector of the transistor 101 in the power amplification circuit 20. At this time, as in the power amplification circuit 10, the comparison voltage Vcomp at the connection point 1033 decreases, and the gain of the transistor 101 drops.

Further, in the power amplification circuit 20, the changing alternating-current voltage caused at the emitter of the transistor 202 may decrease the base voltage of the transistor 202. As in the power amplification circuit 10, the base-emitter voltage of the transistor 202 increases, and the operating point of the transistor 202 consequently moves to a point at which the current IB21, which is the base current supplied to the transistor 202, is smaller. Thus, the change in the operating point of the transistor 202 decreases the base voltage of the transistor 202. If the base voltage of the transistor 202 decreases, the degree of the amplification of the signal RF1 by the transistor 201 decreases, that is, the gain of the transistor 201 drops.

A gain drop may occur at both the transistor 101 and the transistor 201. However, since the transistor 201 is configured to further amplify the signal RF1, which has been amplified by the transistor 101, and output the signal RFout, the amount of a decrease in the output power due to a gain drop is large, and the transistor 201 contributes to the entire gain of the power amplification circuit 20 more than the transistor 101. In short, reducing the gain drop at the transistor 201 is effective to maintain the linearity of the entire gain of the power amplification circuit 20.

As the comparison voltage Vcomp decreases, a difference between the voltage at the non-inverting input terminal and the reference voltage Vref at the inverting input terminal increases in the compensation circuit 104A. The compensation circuit 104A is configured to supply the current Ic to the bias control terminal B2 side based on the voltage difference.

Consequently, the current IB21 supplied to the base of the transistor 202 increases with the current Ic, that is, the current IB21 is compensated with the current Ic. As the current IB21 increases, the bias current IB2 supplied by the transistor 202 to the transistor 201 increases. The increase in the bias current IB2 maintains the bias voltage supplied by the transistor 202 to the transistor 201. In this way, the transistor 201 is able to amplify the signal RF1 more, that is, the gain of the transistor 201 increases. Since the gain of the transistor 201 is kept high, the linearity of the gain of the power amplification circuit 20 is maintained.

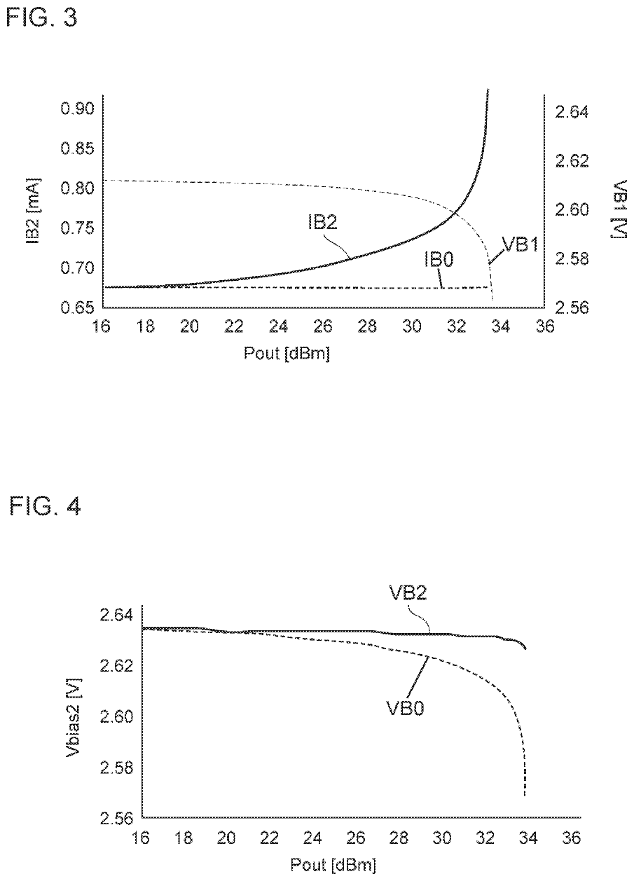

With reference to FIGS. 3 to 5, the linearity of the gain of the power amplification circuit 20 will be described. FIG. 3 depicts a graph in which the bias current IB2 (in mA) of the transistor 201 and the base voltage VB1 (in V) of the transistor 101 are plotted against the output power Pout (in dBm) of the output signal RFout, which is outputted from the transistor 201. Changes in the base voltage VB1 of the transistor 101 are represented by the dotted curve denoted by VB1. Changes in the bias current IB2 in the power amplification circuit 20 are represented by the solid curve denoted by IB2. As a reference example, a corresponding bias current in a power amplification circuit without the comparison-voltage generation circuit 103 and the compensation circuit 104 is represented by the dashed curve denoted by IB0.

As depicted in FIG. 3, the base voltage VB1 of the transistor 101 drops with an increase in the output power Pout. The compensation circuit 104A is configured to detect a drop in the base voltage VB1 and operate to increase the bias current IB2 with a drop in the base voltage VB1. Almost no increase in the bias current is observed under the same condition in the reference example.

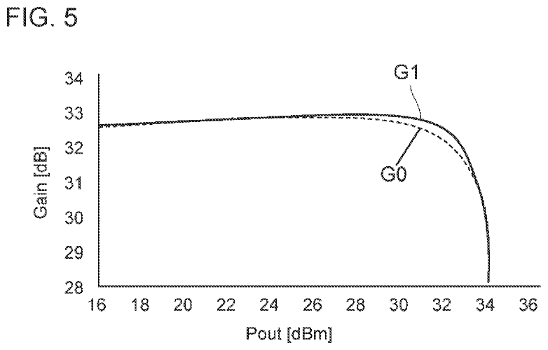

FIG. 4 depicts a graph in which the base voltage Vbias2 (in V) of the transistor 201 is plotted against the output power Pout (in dBm). Changes in the base voltage Vbias2 in the power amplification circuit 20 is represented by the solid curve denoted by VB2. As a reference example, a corresponding base voltage in the power amplification circuit without the comparison-voltage generation circuit 103 and the compensation circuit 104 is represented by the dashed curve denoted by VB0. The base voltage VB2 is kept at a high value because of an increase in the bias current IB2 in the power amplification circuit 20, whereas the base voltage VB0 drops with an increase in the output power Pout in the reference example.

FIG. 5 depicts a graph in which the gain (in dB) of the transistor 201 is plotted against the output power Pout (in dBm). The solid curve denoted by G1 represents changes in the gain of the power amplification circuit 20. The dashed curve denoted by G0 represents the gain in the reference example. The gain G1 is kept at a high value because of an increase in the bias current IB2 in the power amplification circuit 20, whereas the gain G0 drops with an increase in the output power Pout in the reference example. In short, the linearity (flatness of the gain) of the transistor 201 is maintained. In this way, the linearity of the entire power amplification circuit 20 is also maintained.

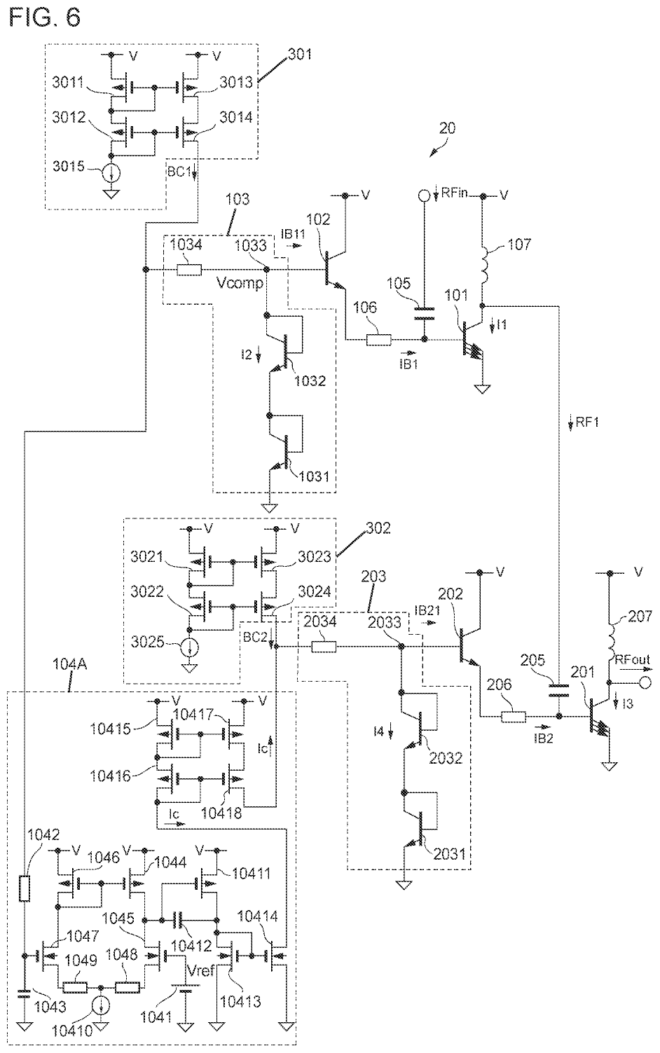

With reference to FIG. 6, a detailed circuit diagram of the power amplification circuit 20 will be described. As depicted in FIG. 6, the power amplification circuit 20 includes a bias control circuit 301 and a bias control circuit 302. The bias control circuit 301 includes transistors 3011, 3012, 3013 and 3014 and a current source 3015. In the bias control circuit 301, the transistors 3011 and 3013 are current-mirror connected, and the transistors 3012 and 3014 are current-mirror connected. The bias control circuit 301 is configured to supply to the transistor 102 a bias control signal BC1 that depends on the current from the current source 3015. The bias control circuit 302 includes transistors 3021, 3022, 3023 and 3024 and a current source 3025. The bias control circuit 302 is configured to supply to the transistor 202 a bias control signal BC2 that depends on the current from the current source 3025.

In addition to the reference voltage source 1041, the compensation circuit 104A includes a resistance element 1042, a capacitor 1043, transistors 1044, 1045, 1046, and 1047, resistance elements 1048 and 1049, a current source 10410, a transistor 10411, a capacitor 10412, and transistors 10413 and 10414. The compensation circuit 104A also includes transistors 10415, 10416, 10417, and 10418 and includes a current mirror circuit connected to the transistor 10414 and the bias control circuit 302.

In the compensation circuit 104A, the gate of the transistor 10414 is configured to receive a voltage depending on a difference between a first voltage and a second voltage, the first voltage being determined by the transistor 1045, which is connected to the reference voltage source 1041, and the transistor 1044, the second voltage depending on Vcomp and being determined by the transistors 1046 and 1047 and the resistance element 1049. The transistor 10414 is configured to draw the current Ic more as the difference between the reference voltage Vref and the comparison voltage Vcomp increases and a higher voltage is supplied to the gate of the transistor 10414.

When the transistor 10414 generates the current Ic, the current mirror circuit formed by the transistors 10415, 10416, 10417, and 10418 reflects the current, and the transistor 10418 supplies the current Ic to the bias control circuit 302 side.

In the second embodiment, the description has been given on the assumption that FETs are used in the compensation circuit 104A and the bias control circuits 301 and 302. Thus, the power amplification circuit 20 may be formed by a first chip and a second chip, the first chip being formed by a bipolar process and including the transistors 101, 102, 201, and 202 and the comparison-voltage generation circuits 103 and 203, the second chip being formed by a CMOS process and including the compensation circuit 104A and the bias control circuits 301 and 302. The amplifying device formed by the transistors 101, 102, 201, and 202 and the comparison-voltage generation circuit 103 and 203 may also be formed by a CMOS process, and the power amplification circuit 20 may be formed by a single chip.

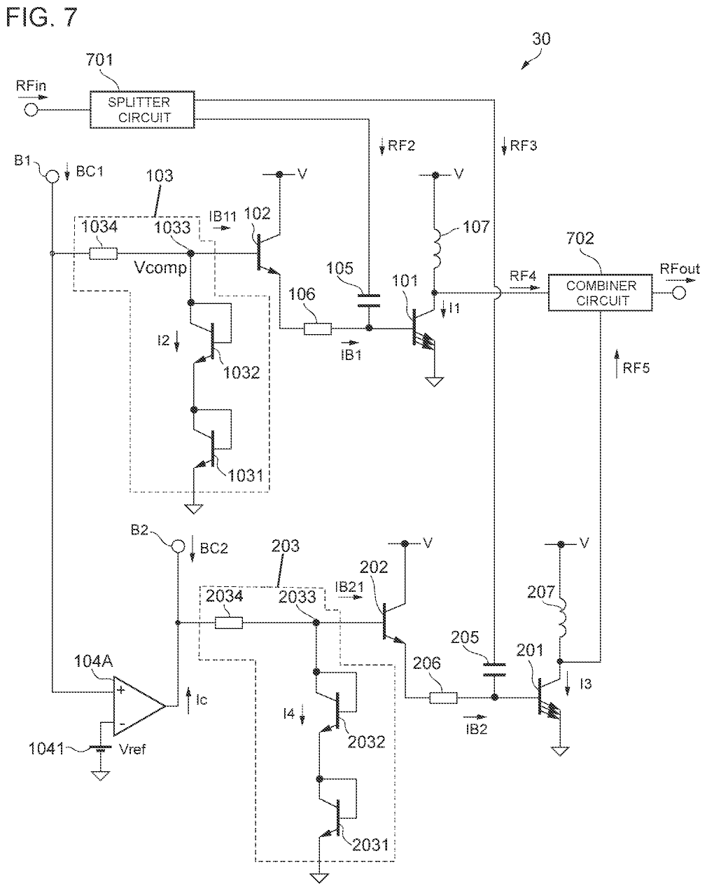

A third embodiment will be described. FIG. 7 is a schematic circuit diagram of a power amplification circuit 30 according to the third embodiment. The power amplification circuit 30 is a Doherty amplification circuit. In addition to the circuit elements described in the second embodiment, the power amplification circuit 30 includes a splitter circuit 701 and a combiner circuit 702.

The splitter circuit 701 is connected to the base of the transistor 101 and the base of the transistor 201. A signal RFin that is inputted to the splitter circuit 701 is split by the splitter circuit 701 into a signal RF2 supplied to the base of the transistor 101 and a signal RF3 supplied to the base of the transistor 201. The splitter circuit 701 may be a commonly available splitter circuit.

In the power amplification circuit 30, the transistor 101 is configured to operate as a carrier amplifier, and the transistor 201 is configured to operate as a peaking amplifier. The transistor 101 is configured to amplify the signal RF2 and output a signal RF4. The transistor 201 is configured to amplify the signal RF3 and output a signal RF5.

The combiner circuit 702 is connected to the collector of the transistor 101 and the collector of the transistor 201. The combiner circuit 702 is configured to combine the signal RF4 from the transistor 101 and the signal RF5 from the transistor 201 and output a signal RFout. The combiner circuit 702 may be a commonly available combiner circuit.

In the power amplification circuit 30, in response to the compensation circuit 104A detecting a decrease in the base voltage of the transistor 101, which is the carrier amplifier, the current Ic is supplied to the transistor 202 side to increase the base current IB2 of the transistor 201, which is the peaking amplifier.

In the Doherty amplification circuit, the transistor 201, which is the peaking amplifier, is configured to operate when the transistor 101, which is the carrier amplifier, is saturated, and the current compensation performed by the compensation circuit 104A enables the base voltage supplied to the transistor 201 to change based on the saturated state of the transistor 101. In this way, in addition to the on and off control of the transistor 201 based on the impedance on the combiner circuit 702 side, the on and off control of the transistor 201 based on the saturated state of the transistor 101 is made possible, and the Doherty amplification circuit may flexibly be controlled.

Some illustrative embodiments of the present disclosure have been described. The power amplification circuits 10, 20, and 30 each include the transistor 101 and the transistor 102, the transistor 101 including the base configured to receive the bias current IB1 or a bias voltage and being configured to amplify the input signal RF2 and output the current I1, the transistor 102 including the emitter connected to the base of the transistor 101 and being configured to supply the bias current IB1 to the base of the transistor 101 from the emitter. The power amplification circuits 10, 20, and 30 each include the comparison-voltage generation circuit 103 and the compensation circuit 104 or 104A. The comparison-voltage generation circuit 103 is configured to generate the comparison voltage Vcomp based on the emitter current or voltage of the transistor 102. The compensation circuits 104 and 104A are each connected to the comparison-voltage generation circuit 103 and is configured to receive the comparison voltage Vcomp and the reference voltage Vref and generate the current Ic with a decrease in the bias current IB1 or the bias voltage of the transistor 101 based on the comparison voltage Vcomp and the reference voltage Vref.

In each of the power amplification circuits 10, 20, and 30, the change in the operating point of the transistor 102 decreases the comparison voltage Vcomp. The compensation circuits 104 and 104A are each configured to generate the current Ic based on the comparison voltage Vcomp and the reference voltage Vref. For example, the generated current Ic is supplied to the transistors 102 and 202 connected to the compensation circuits 104 and 104A, respectively. In this way, the bias voltage supplied by the transistor 102 to the transistor 101 and the bias voltage supplied by the transistor 202 to the transistor 201 are maintained. Thus, the transistors 101 and 201 are each able to amplify the input signal RFin more. In other words, the gains of the transistors 101 and 201 increase. Since the power amplification circuits 10, 20, and 30 are each able to keep the gains of the transistors 101 and 201 high, the linearity of the gain of each of the power amplification circuits is maintained.

In the power amplification circuit 10, the compensation circuit 104 is connected to the base of the transistor 102 and is configured to compensate with the current Ic the current IB11 supplied to the base of the transistor 102.

In this way, in the power amplification circuit 10, the current IB11 is compensated with the current Ic, and the bias voltage supplied by the transistor 102 to the transistor 101 is maintained. Thus, since the gain of the transistor 101 may be kept high, the linearity of the gain of the power amplification circuit 10 is maintained.

The power amplification circuit 10 further includes the bias control circuit 301 that is connected to the base or the gate of the transistor 102 and that is configured to supply the current IB11 to the transistor 102, the compensation circuit 104 is configured to generate the current Ic based on the voltage difference, which is a difference between the comparison voltage Vcomp and the reference voltage Vref, and the current IB11, to which the current Ic has been added, is supplied to the base of the transistor 101.

The decrease in the comparison voltage Vcomp caused by the change in the operating point of the transistor 102 increases the difference between the comparison voltage Vcomp and the reference voltage Vref. The compensation circuit 104 is configured to generate the current Ic based on the voltage difference, compensate the current IB11 with the current Ic, and maintain the bias voltage supplied by the transistor 102 to the transistor 101. Thus, since the gain of the transistor 101 may be kept high, the linearity of the gain of the power amplification circuit 10 is maintained.

The power amplification circuits 20 and 30 each further include the transistor 201 and the transistor 202, the transistor 201 including the base configured to receive the bias current IB2 and being configured to amplify the signal RF3 and output the current I3, the transistor 202 including the emitter connected to the base of the transistor 201 and being configured to supply the bias current IB2 to the base of the transistor 201 from the emitter, and the compensation circuit 104A is connected to the base of the transistor 102 and the base of the transistor 202 and is configured to compensate with the current Ic the current IB21 supplied to the base of the transistor 202.

In this way, in the power amplification circuits 20 and 30, the current IB21 is compensated with the current Ic, and the bias voltage supplied by the transistor 202 to the transistor 201 is maintained. Thus, since the gain of the transistor 201 may be kept high, the linearity of the gain of each of the power amplification circuits 20 and 30 is maintained.

The power amplification circuits 20 and 30 each further include the bias control circuit 302 configured to supply the current IB21 to the base of the transistor 202, the compensation circuit 104A is configured to generate the current Ic based on the voltage difference, which is a difference between the comparison voltage Vcomp and the reference voltage Vref, and the current IB21, to which the current Ic has been added, is supplied to the base of the transistor 202.

The decrease in the comparison voltage Vcomp caused by the change in the operating point of the transistor 102 increases the difference between the comparison voltage Vcomp and the reference voltage Vref. The compensation circuit 104A is configured to generate the current Ic based on the voltage difference, compensate the current IB21 with the current Ic, and maintain the bias voltage supplied by the transistor 202 to the transistor 201. Thus, since the gain of the transistor 201 may be kept high, the linearity of the gain of the power amplification circuit 20 is maintained.

In the power amplification circuit 20, the transistor 101 includes the collector connected to the base of the transistor 201 and is configured to supply the current I1 to the transistor 201 as the signal RF1.

The power amplification circuit 20 is a power amplification circuit having multi-stage connections. Since the power amplification circuit 20 is able to reduce the gain drop of the transistor 201, which is in the subsequent stage and contributes more to the entire gain of the power amplification circuit 20, the linearity of the power amplification circuit 20 is more securely maintained.

The power amplification circuit 30 is a Doherty amplification circuit, the transistor 101 is the carrier amplifier, and the transistor 201 is the peaking amplifier. The power amplification circuit 30 further includes the splitter circuit 701 that is connected to the base of the transistor 101 and the base of the transistor 201 and that is configured to split an input signal into the signal RF2 supplied to the transistor 101 and the signal RF3 supplied to the transistor 201. The power amplification circuit 30 further includes the combiner circuit 702 that is connected to the collector of the transistor 101 and the collector of the transistor 201 and that is configured to combine the current I1 and the current I3.

In the Doherty amplification circuit, the current compensation performed by the compensation circuit 104A enables the base voltage supplied to the transistor 201 to change based on the saturated state of the transistor 101. In this way, in addition to the on and off control of the transistor 201 based on the impedance on the combiner circuit 702 side, the on and off control of the transistor 201 based on the saturated state of the transistor 101 is made possible, and the Doherty amplification circuit may flexibly be controlled.

In each of the power amplification circuits 10, 20, and 30, the comparison-voltage generation circuit 103 further includes the transistor 1032 including the collector connected to the base of the transistor 102, the transistor 1032 including the emitter connected to the collector of the transistor 1031, and the resistance element 1034 disposed between the collector of the transistor 1032 and the compensation circuit 104 or 104A.

The embodiments described above are provided for easy understanding of the present disclosure and should not be construed to limit the present disclosure. Modifications and improvements may be made to the present disclosure without departing from the spirit of the present disclosure, and the equivalents thereof are also encompassed by the present disclosure. That is, these embodiments may appropriately be modified in design by those skilled in the art, and such modifications also fall within the scope of the present disclosure as long as the modifications retain the features of the present disclosure. For example, the elements included in the embodiments and parameters such as arrangement, materials, conditions, shapes, sizes of the elements are not limited to those described in the examples and may be modified appropriately. It is also to be understood that the embodiments have been described for illustrative purposes and that partial substitutions or combinations of the configurations illustrated in the different embodiments may be made, and the scope of the present disclosure also encompasses such substitutions or combinations as long as the substitutions and combinations retain the features of the present disclosure.

<1> A power amplification circuit comprising: a first transistor that includes a base or a gate configured to receive a bias current or voltage and that is configured to amplify an input signal and output a first current; a second transistor that includes an emitter or a source connected to the base or the gate of the first transistor and that is configured to supply the bias current or voltage to the base or the gate of the first transistor from the emitter or the source; a comparison-voltage generation circuit configured to generate a comparison voltage based on an emitter current or voltage of the second transistor; and a compensation circuit that is connected to the comparison-voltage generation circuit and that is configured to receive the comparison voltage and a reference voltage and generate a compensation current with a decrease in the bias current or voltage based on the comparison voltage and the reference voltage.

<2> The power amplification circuit according to <1>, wherein the compensation circuit is connected to a base or a gate of the second transistor, and configured to compensate a second current with the compensation current, the second current being supplied to the base or the gate of the second transistor.

<3> The power amplification circuit according to <2>, further comprising: a bias source connected to the base or the gate of the second transistor and configured to supply the second current to the second transistor, wherein the compensation circuit is configured to generate the compensation current based on a voltage difference that is a difference between the comparison voltage and the reference voltage, and the base or the gate of the second transistor is configured to receive the second current to which the compensation current has been added.

<4> The power amplification circuit according to <1>, the power amplification circuit according to claim 1, wherein the input signal is a first input signal, and the bias current or voltage is a first bias current or voltage, wherein the power amplification circuit further includes a third transistor that includes a base or a gate configured to receive a second bias current or voltage and that is configured to amplify a second input signal and output a third current, and a fourth transistor that includes an emitter or a source connected to the base or the gate of the third transistor and that is configured to supply the second bias current or voltage to the base or the gate of the third transistor from the emitter or the source, and wherein the compensation circuit is connected to a base or a gate of the second transistor and the base or the gate of the fourth transistor and is configured to compensate a fourth current with the compensation current, the fourth current being supplied to the base or the gate of the fourth transistor.

<5> The power amplification circuit according to <4>, further comprising: a bias source configured to supply the fourth current to the base or the gate of the fourth transistor, wherein the compensation circuit is configured to generate the compensation current based on a voltage difference that is a difference between the comparison voltage and the reference voltage, and the base or the gate of the fourth transistor is configured to receive the fourth current to which the compensation current has been added.

<6> The power amplification circuit according to <4> or <5>, wherein the first transistor includes a collector or a drain connected to the base or the gate of the third transistor and is configured to supply the first current to the third transistor as the second input signal.

<7> The power amplification circuit according to <4> or <5>, wherein the power amplification circuit is a Doherty amplification circuit, the first transistor is a carrier amplifier, and the third transistor is a peaking amplifier, and wherein the power amplification circuit further includes a splitter circuit connected to the base or the gate of the first transistor and the base or the gate of the third transistor and configured to split a signal that is inputted to the splitter circuit into the first input signal supplied to the first transistor and the second input signal supplied to the third transistor, and a combiner circuit connected to a collector or a drain of the first transistor and a collector or a drain of the third transistor and configured to combine the first current and the third current.

<8> The power amplification circuit according to any one of <1> to <7>, wherein the comparison-voltage generation circuit further includes a fifth transistor including an emitter connected to ground, a sixth transistor that includes a collector or a drain connected to a base or a gate of the second transistor and that includes an emitter or a source connected to a collector or a drain of the fifth transistor, and a resistance element disposed between the collector or the drain of the fifth transistor and the compensation circuit.

What is claimed is:

1. A power amplification circuit comprising:
a first transistor that has a base or a gate configured to receive a bias current or a bias voltage, and that is configured to amplify an input signal and to output a first current;
a second transistor that has an emitter or a source connected to the base or the gate of the first transistor, and that is configured to supply the bias current or the bias voltage to the base or the gate of the first transistor from the emitter or the source of the second transistor;
a comparison-voltage generation circuit configured to generate a comparison voltage based on an emitter or a source current or voltage of the second transistor; and
a compensation circuit that is connected to the comparison-voltage generation circuit and that is configured to receive the comparison voltage and a reference voltage, and to generate a compensation current that decreases the bias current or the bias voltage based on the comparison voltage and the reference voltage.

2. The power amplification circuit according to claim 1, wherein the compensation circuit is:
connected to a base or a gate of the second transistor, and
configured to compensate a second current with the compensation current, the second current being supplied to the base or the gate of the second transistor.

3. The power amplification circuit according to claim 2, further comprising:
a bias source connected to the base or the gate of the second transistor, and configured to supply the second current to the second transistor,
wherein the compensation circuit is configured to generate the compensation current based on a voltage difference between the comparison voltage and the reference voltage, and
wherein the base or the gate of the second transistor is configured to receive the second current to which the compensation current has been added.

4. The power amplification circuit according to claim 1,
wherein the input signal is a first input signal, and the bias current or the bias voltage is a first bias current or a first bias voltage,
wherein the power amplification circuit further comprises:
a third transistor that has a base or a gate configured to receive a second bias current or a second bias voltage, and that is configured to amplify a second input signal and to output a third current; and
a fourth transistor that has an emitter or a source connected to the base or the gate of the third transistor, and that is configured to supply the second bias current or the second bias voltage to the base or the gate of the third transistor from the emitter or the source of the fourth transistor, and
wherein the compensation circuit is connected to a base or a gate of the second transistor and a base or a gate of the fourth transistor, and is configured to compensate a fourth current with the compensation current, the fourth current being supplied to the base or the gate of the fourth transistor.

5. The power amplification circuit according to claim 4, further comprising:
a bias source configured to supply the fourth current to the base or the gate of the fourth transistor,
wherein the compensation circuit is configured to generate the compensation current based on a voltage difference between the comparison voltage and the reference voltage, and
wherein the base or the gate of the fourth transistor is configured to receive the fourth current to which the compensation current has been added.

6. The power amplification circuit according to claim 4, wherein the first transistor has a collector or a drain connected to the base or the gate of the third transistor, and is configured to supply the first current to the third transistor as the second input signal.

7. The power amplification circuit according to claim 4,
wherein the power amplification circuit is a Doherty amplification circuit,
wherein the first transistor is a carrier amplifier,
wherein the third transistor is a peaking amplifier, and
wherein the power amplification circuit further comprises:
a splitter circuit connected to the base or the gate of the first transistor and to the base or the gate of the third transistor, and configured to split a signal that is inputted to the splitter circuit into the first input signal supplied to the first transistor and the second input signal supplied to the third transistor; and
a combiner circuit connected to a collector or a drain of the first transistor and to a collector or a drain of the third transistor, and configured to combine the first current and the third current.

8. The power amplification circuit according to claim 1, wherein the comparison-voltage generation circuit comprises:
a fifth transistor having an emitter or a source connected to ground;
a sixth transistor that has a collector or a drain connected to a base or a gate of the second transistor, and that has an emitter or a source connected to a collector or a drain of the fifth transistor; and
a resistance circuit element between the collector or the drain of the sixth transistor and the compensation circuit.
